(19) United States
(12) Patent Application Publication
(10) Pub. No.: US 2008/0074293 A1
(43) Pub. Date: Mar. 27, 2008

(54) Input apparatus, input control method, and computer-readable recording media for input control program

(75) Inventors: Sachiko Yoshimura, Osaka (JP); Keiko Fujii, Osaka (JP); Issei Tsuhara, Osaka (JP)

Correspondence Address: DILWORTH & BARRESE, LLP, 333 EARLE OVINGTON BLVD., SUITE 702, UNIONDALE, NY, 11553, US

(73) Assignee: Kyocera Mita Corporation, Osaka (JP)

(21) Appl. No.: 11/903,664

(22) Filed: Sep. 24, 2007

(30) Foreign Application Priority Data
Sep. 26, 2006 (JP) 2006-260080

(51) Int. Cl. H03K 17/94

(52) U.S. Cl. 341/23

(57) ABSTRACT

An input apparatus and an input control method are provided that enable the confirmation of an operation state using speech each time an operation key is depressed and enable the execution of distributed functions using a straightforward operation. A plurality of functions is allocated to a numeric keypad, and audio is outputted for the operation state by way of the numeric keypad from an audio output section every time an operation function changes. A function just previous to operation of the numeric keypad can, therefore, be decided by using a setting key, and control may be carried out by a control unit.

This application is based on and claims the benefit of priority from Japanese Patent Application No. 2006-260080, filed on 26 Sep. 2006, the content of which is incorporated herein by reference.

### BACKGROUND OF THE INVENTION

1. Field of the Invention

The present invention relates to an input apparatus, an input control method, and an input control program for inputting characters, etc.

2. Related Art

Conventionally, an input apparatus where an operation section is provided with a plurality of operation keys, with a plurality of functions being allocated to each key, as typified by a so-called numeric keypad, are well-known as a way of effectively utilizing installation space to implement a plurality of functions.

This operation section may be provided with, for example, numeric keys from “0” to “9”, symbol keys such as “*” and “#”, and a joy stick that goes up, down, left, right, etc. It is then possible to switch between functions such as numeric input, alphabetic input, and kana input according to an operating state (operation mode, input mode, etc.).

For example, with Japanese language input, in the case of inputting kana characters of “o”, “ha”, “yo”, “u”, etc. (where “o”, “ha”, “yo”, and “u” are kana characters shown in Hepburn-Romanized form), it is possible to call up “o” by depressing key 1 allocated with an input function for the “aa” group of kana characters five times (“o” is at a fifth position of an “a” group). Display of the state of switching from “a” to “o” is switched over each time key 1 is depressed at “o” at a display section of a liquid crystal monitor, etc. In the following, it is possible to call up “ha” (where “ha” is at a first position of a “ha” group) by depressing key 6 allocated with the “ha” group kana input function one time. It is possible to call up “yo” (where “yo” is at a third position of a “ya” group) by depressing key 8 allocated to a “ya” group kana input function three times. It is also possible to call “u” (where “u” is at a third position of the “a” group) by depressing key 1 allocated with the “a” group kana input function three times.

During this time, it is possible for a user to perform allocation and identification while having characters to be allocated such as “1”, “a” (the “a” group), and “ABC”, etc. share a single key, by confirming characters in order to recognize the allocation displayed for each key.

On the other hand, with this kind of input apparatus, miniaturization of each operation key as a result of miniaturizing the electronic equipment on which this input apparatus is mounted is advancing, while at the same time, the allocated characters are also becoming smaller.

It is, therefore, difficult for a person that is visually impaired such as a person with weak eyesight to identify each key allocation. This may then cause errors in operation.

Technology for giving notification using speech, etc. in response to operation of operation keys in such a manner as to make confirmation that operation of each operation key is actually a straightforward desired operation, even for users that are visually impaired, is well-known.

In technology disclosed in a certain related art, by depressing the same operation key two times in succession when in an audio output mode, it is possible to perform selection with the first time depressing, and to execute audio output with the second time depressing.

When “o” described above is called, “a” is selected by pressing down key 1 one time. Speech for “a” is then outputted by operating the key 1 a second time. “e” is selected by then operating the key 1 a third time. Speech for “e” is then outputted by a fourth operation of the key 1. Thereafter, “o” is selected by a ninth operation of key 1 and speech for “o” is outputted by a tenth operation of the key 1.

With technology disclosed in a further related art, when the operation key and the operation setting key have a one-to-one correspondence with respect to function, speech is outputted when an operation key is depressed. If the speech is confirmed to be correct, the operation setting key is depressed and an operation is selected. If the speech is confirmed to be incorrect, another operation key is depressed and a correct operation key is selected. It is also possible during this time for confirmation speech to be outputted again when the same operation key continues to be depressed for a predetermined time.

However, with the input apparatus of the configuration described above of, for example, the technology disclosed in the related art, the same operation key is depressed two consecutive times, performing selection with depressing the first time, and outputting speech with depressing the second time. This means that it is necessary to depress ten times in the case of selecting “o” described above and this operation is, therefore, troublesome.

Furthermore, with the technology disclosed in a further related art, there is a one-to-one correspondence with respect to the function of the operation keys and operation setting keys. Application to an input apparatus where a plurality of functions is allocated to the same operation key is, therefore, not possible.

Moreover, with the technology disclosed in yet another related art, speech is outputted only when the function it is desired to adopt is finally decided. This means that, for example, when it is desired to input “o” by pressing a key 1 five times, if a key 2 of the “ka” group is mistakenly pressed five times, there is the problem that it is not possible to confirm that a mistaken operation has been made until the speech for “ko” is outputted.

### SUMMARY OF THE INVENTION

An input apparatus of an aspect of the present invention, therefore, includes an operation section having a plurality of operation keys, with a plurality of functions allocated to each operation key, a setting key for selecting upon a function operated just previously at each operation key, and a control circuit for controlling the operation section and the setting key.

According to an input apparatus of the aspect of the present invention, it is possible to execute distributed functions using a straightforward operation.

### BRIEF DESCRIPTION OF THE DRAWINGS

FIG. 1 is an external perspective view of multifunction equipment taken as electronic equipment equipped with an input apparatus of an embodiment of the present invention;

FIG. 2 is a front view of an operation section of multifunction equipment taken as electronic equipment equipped with an input apparatus of the embodiment of the present invention; and

FIG. 3 is a flowchart of an example of operation control of an input apparatus of the embodiment of the present invention.

### DETAILED DESCRIPTION OF THE PREFERRED EMBODIMENT

A description is provided with reference to the drawings of an input apparatus of an embodiment of the present invention applied to an image forming apparatus (multifunction equipment) taken as electronic equipment.

### Overall Configuration of Multifunction Equipment

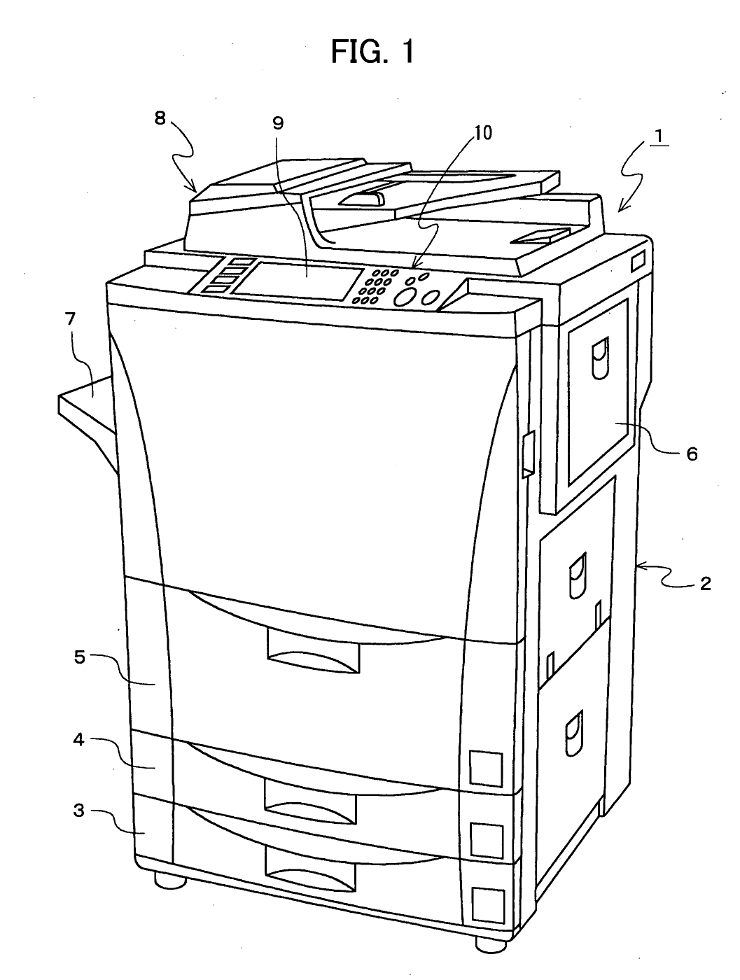

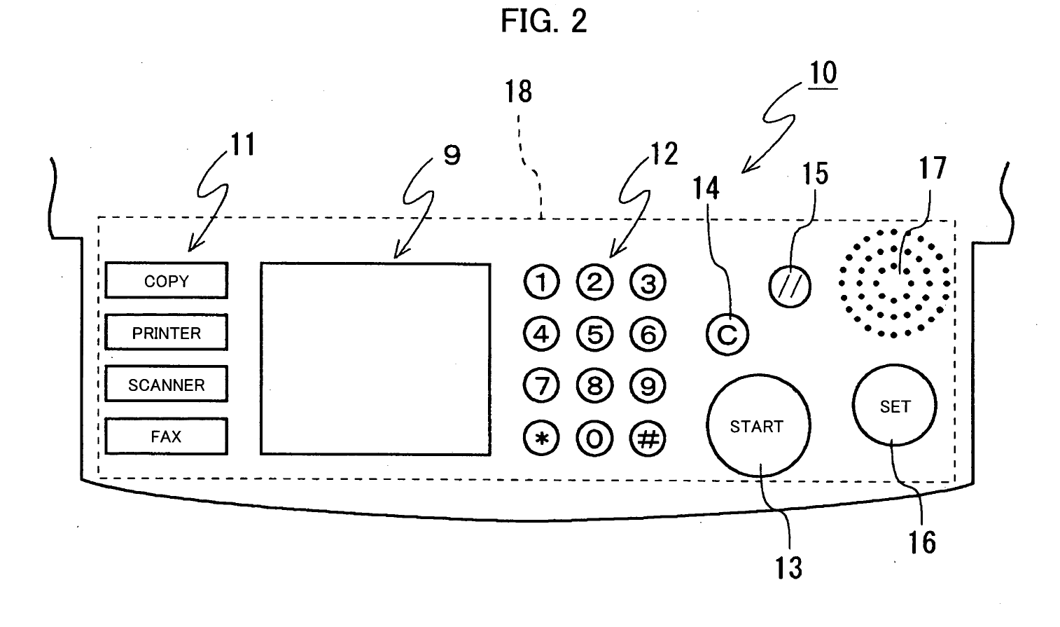

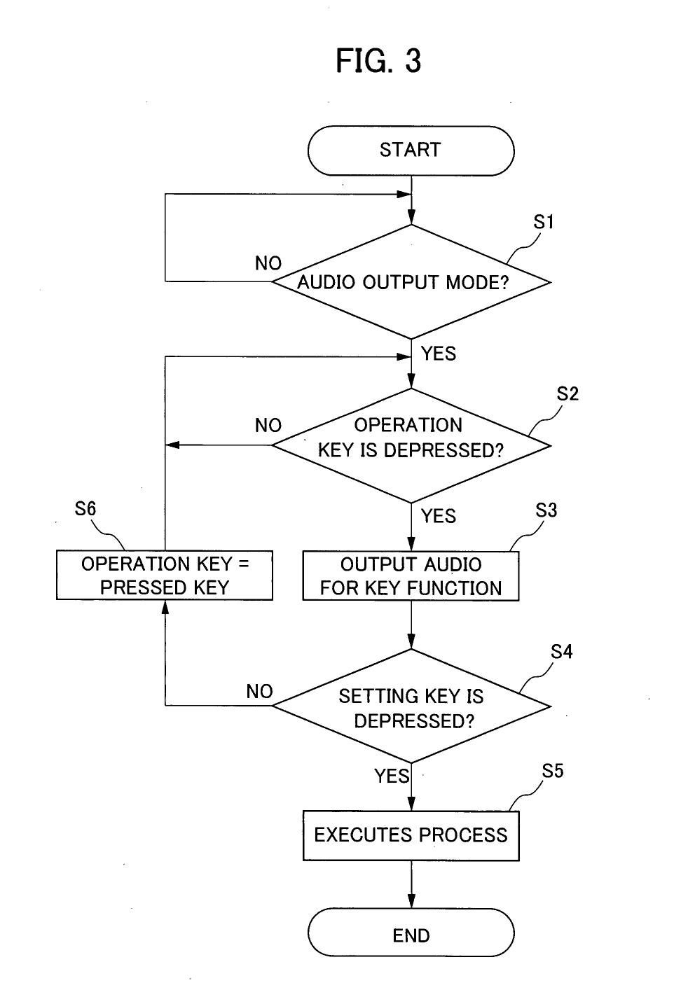

FIG. 1 is an external perspective view of multifunction equipment taken as electronic equipment equipped with an input apparatus of the embodiment of the present invention. FIG. 2 is a front view of an operation section of the multifunction equipment as electronic equipment equipped with an input apparatus of the embodiment of the present invention. FIG. 3 is a flowchart of an example of operation control of an input apparatus of the embodiment of the present invention.

As shown in FIG. 1, multifunction equipment 1 as electronic equipment equipped with an input apparatus of the embodiment of the present invention includes: a plurality of levels of paper tray units 3, 4, and 5 capable of being pulled out from the front surface of an apparatus body 2; a manually fed paper tray 6 capable of being opened and closed from one side of the apparatus body 2; a paper ejection tray 7 projecting from the other side of the apparatus body 2; an automatic document feeder (ADF) 8 for reading original manuscripts for copying, faxing, or scanning; and an operation section 10 having a display screen 9 and carrying out setting and selection of various functions, etc.

The shape, configuration, and function, etc. of the multifunction equipment 1 is by no means limited to the example shown in the drawings. Installation of optional equipment, etc. such as, for example, a sorter, is also by no means hindered.

### Configuration of Operation Section 10

As shown in FIG. 2, the operation section 10 is configured of function select keys 11, next to a display screen 9 as a liquid crystal panel switch, for selecting various functions (copy function, printer function, scanner function, and facsimile function) of the multifunction equipment 1, a numeric keypad 12 used when inputting numerals and alphabetic characters for a number of copies, enlargement/reduction rate, destination telephone number, or destination name, etc., a start key 13 for executing (starting image forming) copy functions and facsimile functions, a clear settings key 14, a function reset key 15, a setting key 16 for selecting an audio output mode and confirming (executing) operations, and an audio output section 17 for outputting a function using speech every time each of the various keys 11 to 16 is depressed.

The display screen 9 and the operation section 10 combine operation functions for carrying out various settings such as paper size setting, concentration setting, double-sided printing setting, or intensity setting, etc., during utilization of copy functions, etc. according to the function of the multifunction equipment 1. The control and audio output relating to the operations for these various functions is controlled by a control circuit board (control circuit) 18 incorporated in the apparatus body 2.

Furthermore, the numeric keypad 12 may be allocated to function as single digits of Arabic numerals, 50 Japanese syllabury lined up in groups, voiced sounds and prolonged sounds, etc., alphabetical characters, etc., and other symbols at, for example, each key 0 to 9. For example, Arabic numeral “1”, kana of “a”, “i”, “u”, “e”, “o”, and alphabetical characters of “A”, “B” and “C” may be allocated to key 1 as one type of numeric and character function.

As a result, for example, in the event of depressing a “fax” key of the function select keys 11 and utilizing a panel switch function displayed at the display screen 9 so as to select quick dial registration mode. etc., each of the keys “0” to “9” may function as numerals when inputting a facsimile number of a destination for quick dial registration, and each of the keys “0” to “9” may function as characters (kana input function/alphabetical character input function) when inputting a name for a destination for quick dial registration.

Furthermore, this input information is displayed on the display screen 9, and can be switched over between converting to kanji, inputting kana or inputting alphabetical characters as necessary.

### SPECIFIC CONTROL EXAMPLE

The following is a description with reference to the flowchart of FIG. 3 of an application of an example of control occurring at the control circuit 18 of the input apparatus of the present invention at the time of inputting kana using the numeric keypad 12.

### (Step S1)

In step S1, the control circuit 18 monitors whether or not audio output mode is selected. When audio output mode is selected, step S2 is advanced to. When audio output mode is not selected, monitoring continues in step S1.

Furthermore, an audio output mode that is useful for the visually impaired, etc. is selected by depressing the setting key 16 for an extended duration. Speech such as “audio output mode selected” is then outputted by the audio output section 17. Moreover, it is also possible to provide a backlight at the back surface of the setting key 16 and illuminate the backlight or to arrange an indicator such as an LED directly in front of the setting key 16 and illuminate this indicator in such a manner as to enable confirmation that the audio output mode is selected. In addition, selection of audio output mode is arbitrary and may be automatically switched using registration of a user card, etc., selection utilizing a panel switch function of the display screen 9, or an audio output mode selection key may be separately provided. It is also possible to provide unevenness at the surface in order to make it easy to be aware of the presence of the setting key 16.

In addition to outputting speech for function keys used in common such as for the numeric keypad 12 shown below when the audio output mode is being executed, the audio output described above is also possible when a dedicated key such as a function select key 11 is depressed.

Moreover, a publicly known common operation is effective when the numeric keypad 12 is depressed in a state where audio output mode is not selected and this is, therefore, not described here.

### (Step S2)

In step S2, the control circuit 18 monitors whether or not any key of the numeric keypad 12 as operation keys is depressed. When any key of the numeric keypad 12 is depressed, step S3 is advanced to. When none of the keys of the numeric keypad 12 are depressed, observation continues in step S2.

### (Step S3)

In step S3, the control circuit 18 outputs speech corresponding to a function allocated to the numeric keypad 12 that is pressed from the audio output section 17 and step S4 is advanced to.

### (Step S4)

In step S4, the control circuit 18 monitors whether or not the setting key 16 is depressed. When the setting key 16 is depressed, step S5 is advanced to. When the setting key 16 is not depressed, step S6 is advanced to.

### (Step S5)

In step S5, when the setting key 16 is depressed, the control circuit 18 executes processing taking the operation key depressed just previously in step S2 (operated by a person) as a key depressed to select a function.

### (Step S6)

In step S6, the control circuit 18 returns to step S2 taking the operation key depressed in step S2 as a temporarily pressed key.

Character functions for “a”, “i”, “u”, “e”, and “o” are allocated to one key 1 of the numeric keypad 12. When this character function is selected, by depressing key 1 a first time, speech for “a” is outputted from the audio output section in step S3. When the setting key 16 is then depressed in step S4, functioning as “a” is selected (executed). Furthermore, when the decide key 16 is not depressed in step S4, “a” is made effective temporarily using the audio output of “a” in step S3. When the operation key pressed a second time in step S2 is key 1, functioning as “a” is cancelled and functioning as “i” is selected.

During this time, in the second time of step S2, when, for example, key 2 is depressed, the operation of key 1 the first time becomes invalid.

When the same key 1 is depressed on condition that the decide key 16 has not been depressed, functions for “a”→“i”→“u”→“e”→“o”→“a”→“i”→ . . . are sequentially selected each time depressing, with speech for “a”→“i”→“u”→“e”→“o”→“a”→“i” . . . being sequentially outputted from the audio output section 17 each time.

Furthermore, when key 1 is depressed after the setting key 16 is depressed, this key 1 is recognized as being a newly operated key.

In this way, in the operation section 10 of the present invention, an allocated function is switched to each time the same key of the numeric keypad 12 is depressed with the audio output mode selected. Speech corresponding to this function is then outputted from the audio output section 17 and the immediately previous function is confirmed when the setting key 16 is depressed. It is, therefore, possible to make decisions together with function switching through a small number of key operations, and it is possible to confirm operations using audio output (every time an operation key is depressed).

Therefore, when speech is outputted only when the setting key 16 is operated, then the inconvenience where an error in operation is only recognized for the first time when, for example, the setting key 16 is depressed in a state where “o” is selected after key 1 has been depressed five times in error, where it was actually desired to select “ko” by depressing key 2 five times, is avoided.

The control circuit 18 is arranged in such a manner that a directly preceding operation with processing different than processing during depressing of another operation key in step S2 that passed through step S6 is not cancelled, as a result of allocating an operation key (for example, “#” key, etc.) when a voiced sound, etc. is selected as a special key.

This therefore maintains versatility such as providing “ba” when the “#” key is depressed once with the “ha” key selected, and providing “pa” when depressed twice. Furthermore, audio output takes place from the audio output section 17 even for “ba” and “pa” during this time.

In the above embodiment, a description is provided of application of an input apparatus of the present invention to an image forming apparatus (multifunction equipment) as electronic equipment. However, general application is also possible to parts of electronic equipment or to numeric keypads that are connectable to electronic equipment (computers, etc.) provided that a plurality of operation keys such as for the numeric keypad 12 is provided and operation functions are provided in such a manner that a plurality of functions is allocated to each operation key.

Moreover, in addition to switching over functions every time depressing takes place, it is also possible for functions of the numeric keypad 12 to be switched every predetermined time (for example, one second) as a result of prolonged depressing, with setting also being possible so as to provide audio output every time of switching.

What is claimed is:

1. An input apparatus comprising:
an operation section having a plurality of operation keys, with a plurality of functions allocated to each operation key;
a setting key that decides upon a function operated just previously by each operation key; and
a control circuit that decides the operation section and the setting key.

2. The input apparatus according to claim 1, further comprising an audio output section that outputs speech of an operation state for each operation key each time an operation function changes.

3. The input apparatus according to claim 1, wherein the control circuit switches an allocated function every time the same operation key is depressed.

4. The input apparatus according to claim 1, wherein the control circuit switches an allocated function every time the same operation key is depressed continuously for a predetermined duration.

5. The input apparatus according to claim 1, wherein, when a second operation key that is different to the setting key is depressed, the control circuit invalidates an operation of an operation key operated immediately previous to operation of the second operation key.

6. An input control method comprising steps of:
extracting a function allocated to an operated operation key of a plurality of operation keys allocated with a plurality of functions, respectively; and
executing the function extracted just previous in the extracting step as a result of operation of a setting key.

7. A computer-readable recording medium storing a program that executes steps of:
extracting a function allocated to an operated operation key of a plurality of operation keys allocated with a plurality of functions, respectively; and
executing the function extracted immediately previously in the extracting step as a result of operation of a setting key on a computer.
